(19) United States
(12) Patent Application Publication
(10) Pub. No.: US 2015/0229439 A1
(43) Pub. Date: Aug. 13, 2015

(54) COMMUNICATION APPLICATIONS

(71) Applicant: HALLIBURTON ENERGY SERVICES, INC., Houston, TX (US)

(72) Inventors: Victor James Stolpman, Houston, TX (US); Ehud Barak, Houston, TX (US)

(21) Appl. No.: 14/432,434

(22) PCT Filed: Nov. 27, 2012
(86) PCT No.: PCT/US2012/066643

§ 371 Date: Mar. 30, 2015

(51) Int. Cl. H04L 1/00; H04L 27/26; H03M 13/00; H04L 5/00

(52) U.S. Cl. CPC H04L 1/0041; H04L 5/0094; H04L 5/0046; H04L 27/26; H03M 13/635

(57) ABSTRACT

In some embodiments, an apparatus and a system, as well as a method and an article, may operate to determine a uniform number of bits per sub-carrier and an error correction rate as part of a communication system configuration to maximize the effective bit transmission rate while minimizing the size of the configuration description, using a predetermined number of bits. The configuration description designates at least the number of bits per sub-carrier, the error correction rate, and the number of sub-carriers. Additional apparatus, systems, and methods are described.

### BACKGROUND

Drilling rig operators often employ the use of Measurement-While-Drilling (MWD) and Logging-While-Drilling (LWD) tools and services during drilling operations, to measure and/or log various conditions within the borehole and/or the rock formations surrounding the borehole. MWD/LWD tools utilize a variety of sensors to sample and aggregate digital values for real-time transmission to the surface during drilling operations. The transmission scheme and channel medium may vary. For example, they may include Mud Pulse Telemetry (MPT) through water and drilling mud, Electro-Magnetic-Telemetry (EMT) through rock formations, and Acoustic Telemetry (AT) via the drill-string. Each scheme typically employs some form of modulation (e.g. Pulse-Position-Modulation (PPM), Orthogonal Frequency Division Multiplexed (OFDM), and Direct Sequence Spread Spectrum (DSSS)) to increase the reliability of communication through the associated medium.

Because the signal-to-noise ratio (SNR) for a given communication channel often depends on the formation characteristics and the depth of the bit, the most useful configuration of the modulation scheme (e.g., the number of bits per sub-carrier, the error correction rate, etc.) may change frequently. When this happens, the down hole transmitter receives new configuration information from the equipment on the surface, so that its operational mode can be changed. Since the bandwidth of communication within the formation is very low, it is desirable to minimize the amount of configuration information that is sent to the transmitter.

### BRIEF DESCRIPTION OF THE DRAWINGS

FIG. 1 illustrates examples of scrambler transforms at the transmitter and the receiver, according to various embodiments of the invention.

FIG. 2 illustrates a bit-stream format concatenating fixed length packets with SEED and POLY values, according to various embodiments of the invention.

FIGS. 3-4 illustrate block diagrams of transmitters and receivers, according to various embodiments of the invention.

FIG. 5 is a block diagram of apparatus and systems according to various embodiments of the invention.

FIG. 6 is a flow chart illustrating several methods according to various embodiments of the invention.

FIG. 7 illustrates a wireline system embodiment of the invention.

FIG. 8 illustrates a drilling rig system embodiment of the invention.

FIG. 9 is a block diagram of an article according to various embodiments of the invention.

### DETAILED DESCRIPTION

### Introduction

As noted previously, drilling rig operators often employ MWD and LWD tools and services during drilling operations, to measure and/or log various conditions within the borehole and/or the rock formations surrounding the borehole. MWD/LWD tools utilize a variety of sensors to sample and aggregate digital values for real-time transmission to the surface during drilling operations. The transmission scheme and channel medium may vary. One of the methods used is EMT through rock formations. To increase the reliability of communication through this medium, different forms of modulation may be used.

Thus, various modulation techniques, some using multiple sub-carriers, can be used to encode the data onto a signal, often using the formation itself as the communication channel OFDM is one of the modulation schemes used to obtain both high reliability and high data rate. In OFDM, each sub-carrier can be loaded with a different bit constellation before transmission to the surface.

OFDM thus uses multiple sub-carriers to transport data, which may be scrambled prior to modulation. The data is encoded on each sub-carrier as phase and amplitude and is transmitted using symbols. For each symbol, a new phase and amplitude is transmitted on each sub-carrier. In general, the number of bits that can be loaded onto each sub-carrier depends on the sub-carrier SNR. When operating an OFDM modem, it is useful to select the configuration of each channel, including the error correction rate, which provides the best overall bit rate while keeping the error probability below a fixed amount. The power that is allocated to each sub-carrier can also be changed.

Any process used to find the most useful configuration should be efficient, so that transmission won't be unduly delayed. Moreover, the configuration information should be as compact as possible, to make the best use of available bandwidth. To address some of these challenges, as well as others, apparatus, systems, and methods are described herein to determine a constellation configuration and an error correction rate that maximizes the total bit rate within a fixed total power budget—while reducing the number of bits used to convey configuration information (designated herein as a “configuration description”) as much as possible. This latter consideration is quite useful with respect to OFDM communications that occur between locations connected via an inherently “slow” communications channel, such the bottom hole assembly (BHA) and the surface, coupled by a geological formation that is used as the communications channel.

Some features of the searching algorithm include consideration of three parameters: which sub-carriers should be used, which constellations to use on each sub-carrier, and which error correction rate to use. The algorithm attempts to reduce the size of the configuration description with a minimal effect on the overall communication bit rate. For the purposes of this document, a “configuration description” means a collection of bits that defines at least: the number of sub-carriers, the number of bits per sub-carrier, and the error correction rate.

In some embodiments, a method is described that optimizes EMT service using OFDM signaling in situ via limited feedback. More specifically, the method can operate to select and configure the OFDM Modulation Coding Scheme (MCS). Configuration selection is useful because it permits more efficient use of the available power and bandwidth (dictated by the communication channel, e.g. rock formations) in order to maximize an information data rate subject to an error constraint and a limited power constraint. In other words, a transmitter configured too aggressively with respect to data rate will result in many errors at the receiving end of the communication link. On the other hand, a transmitter configured too conservatively will use either too much power and/or be inefficient with respect to the available bandwidth, resulting in the transmission of information less rapidly than might otherwise be possible.

Decisions facing EMT systems utilizing OFDM include: sub-carrier allocation/enablement, power allocation, bit allocation, error correction coding (ECC)/forward error correction (FEC) code rates (e.g., the ratio of information rate over the total bit rate, including information and parity), and error placement, if any. The mechanism described herein uses SNR measurements at the receiver to determine a configuration to optimize spectral and power usage either at the surface or in situ subject to the transmitter having a priori knowledge of power capabilities. Because noise power and channel response may be heterogeneous across the sub-carriers of an OFDM system, it is useful to know which carriers to use and how many bits to load onto each carrier. The system should operate to identify these items when selecting an ECC/FEC code to efficiently utilize the tradeoff additional parity in the adjustment of the information data rate.

With the use of error correction coding (e.g. convolutional coding) in an EMT communication system, an efficient way to maximize the effective information throughput between the down hole transmitter and the surface receiver is useful. This can help increase the effective rate of communication both uplink and downlink data.

Rig time cost is also a factor. Solutions should operate to reconfigure quickly as drilling conditions change, since different formations often have different channel characteristics. In order to accomplish this, most embodiments limit the total number of bits used in the configuration description. Under conditions where the communications channel severely limits throughput, a minimal overhead has even greater value—especially when OFDM or other multi-stream signaling is used. The following sections describe some embodiments of a mechanism to limit the number of configurations needed, which is sometimes sub-optimal, but in many cases very close to optimal.

As used in this document, a “scrambler” is a processing device comprising electrical hardware that operates to manipulate a data stream before transmission into a communications channel. The manipulations are reversed by a “descrambler” at the receiving end of the communications channel Scrambler types may include additive and multiplicative scramblers.

Scrambling is widely used in satellite, radio relay communications, and PSTN (public switched telephone network) modems. In some embodiments, a scrambler is placed just before a FEC (forward error correction) coder, or it can be placed after the FEC, just before the modulation or line coder. A scrambler in this context has nothing to do with encrypting, as the intent is not to render the message unintelligible, but to impart useful properties to the transmitted signal. For example, the scrambler may operate to transform digital sequences into other sequences, without removing undesirable sequences, to reduce the probability of vexatious sequence occurrence.

Thus, some embodiments may include a system to communicate through a rock formation that comprises a transmitter configured to modulate a current with transformed digital data and to transmit the modulated current through a rock formation. The modulated current may comprise a superposition of a plurality of waveforms. The system may further include a receiver configured to demodulate the current, to select a transform from a plurality of transforms, and to use the selected transform to operate on the demodulated information, providing the digital data forming part of at least one packet, using an error detection code.

### Data Transmission and Reception

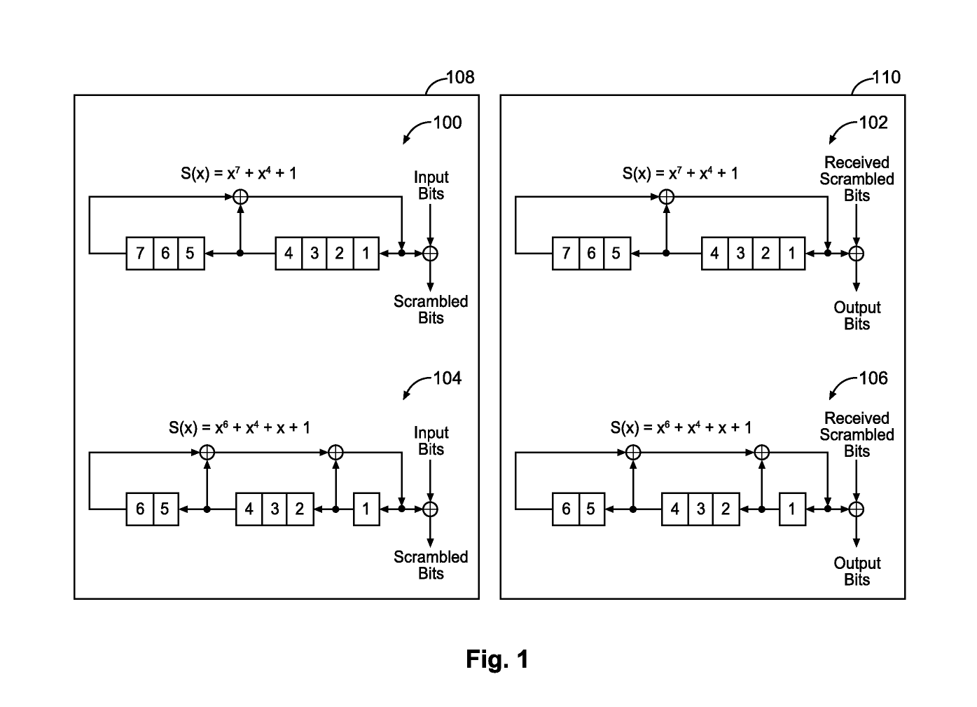

FIG. 1 illustrates examples of scrambler transforms 100, 102, 104, 106 at the transmitter and the receiver, according to various embodiments of the invention. Thus at the transmitter, one embodiment uses a transform selected from a set of transforms 100, 104 where each comprises a linear feedback shift register (LFSR) configured according to a polynomial descriptor. Each register can accept an initial state value/indicator for the memory elements within the LFSR. The number of memory elements may indicate the largest possible cardinality of the transform set. Thus, the transmitter may have at least one scrambler 108 that includes one or more transforms 100, 104, perhaps taking the form of LSFRs, to transform, e.g. scramble, digital values according to a polynomial indicator and an initial value, possibly using Galois Field arithmetic (GF), such as modulo-2 arithmetic. The transforms 100, 102, 104, 106 may also be implemented with hardware or hardware executing software/firmware instructions that provides a unitary transform, spherical codes, and other matrix transforms.

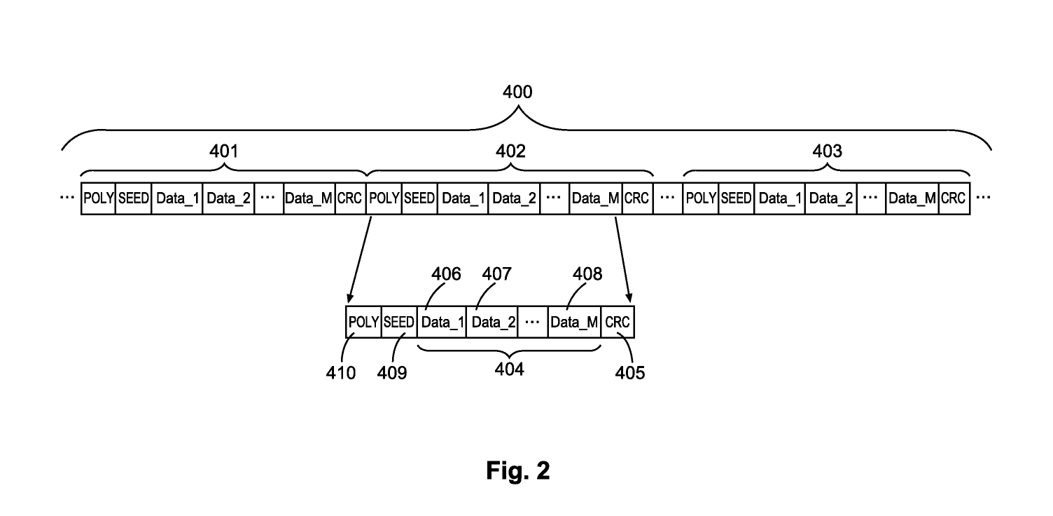

FIG. 2 illustrates a bit-stream format 400 concatenating fixed length packets 401, 402, 403 with SEED and POLY values 409, 410, according to various embodiments of the invention. Here each packet 401, 402, 403 includes information in the form of data 404 (e.g., bits, bytes or words 406, 407, 408), cyclic redundancy check information 405, a SEED value 409, and a POLY value 410, which represents the polynomial descriptor for the transform that has been selected, perhaps to be implemented by an LFSR. In some embodiments, the packets 401, 402, 403 are not of a fixed length. In some embodiments, the transmission of the SEED, POLY, and/or CRC values is optional. The current configuration description can be sent via one of the packets 401, 402, 403, perhaps as data 404.

Thus, transmitters may operate to select different initial content values, or SEEDs, for one or more LSFRs. Transmitters that operate in this manner may transform a given set of digital data input bits differently, using different SEEDs. The transmitter can then include the selected SEED within the bit-stream modulated for transmission, as shown in the figure.

A controller within the transmitter may operate to account for the SEED initial value indicator, perhaps as part of calculating optimization metrics for each possible SEED given a LSFR configured to implement a particular polynomial descriptor, POLY. Thus, transmitters in some embodiments may use a predetermined optimization criterion. In other embodiments, the SEED and/or POLY values that pertain to the transform used at the transmitter may or may not be included in the formatted bit-stream and/or encoded, modulated waveforms. Likewise, various receiver embodiments at the receiver may or may not use any SEED and/or POLY values to decode transmitted packets. This tradeoff may involve additional receiver complexity (more calculations), as various possible combinations for SEED and/or POLY various are tested to determine which produces a series of correctly unscrambled packets.

In some embodiments, a controller calculates at least one optimization metric relating to a predetermined criterion (e.g., selecting a threshold acceptable error rate) for at least one transform within a plurality of transforms. The controller may include a memory device to store one or more optimization metrics, as determined by a predetermined criterion.

### Transmitters and Receivers

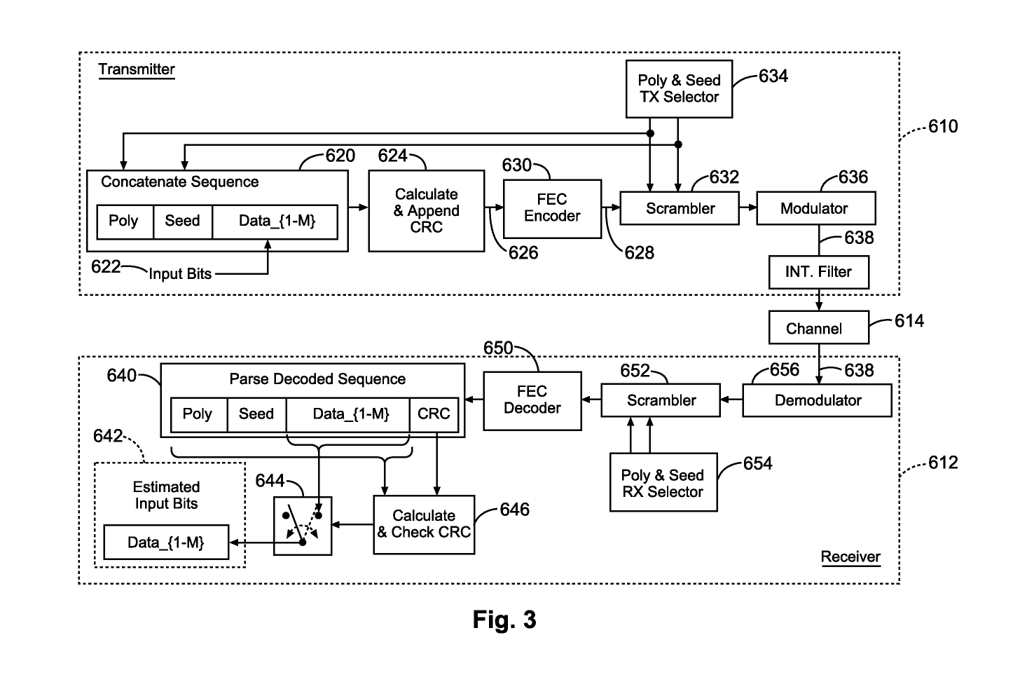

FIG. 3 illustrates a block diagram of a transmitter 610 and receiver 612, according to various embodiments of the invention. Here, it can be seen that a transmitter can operate on a concatenated sequence of information (comprising SEED and POLY values, as well as a data payload 622, which may include a configuration description, as noted below) 620.

A transmitted CRC processor 624 can operate on its input (the information 620 in this case) to calculate and append a CRC value to the information 620. An FEC encoder 630 may operate on its input (the information 620, augmented by an associated CRC value in this case, which provides augmented information 626) to calculate and append error correcting code(s) to the augmented information 626, providing additional information 628.

The output of the FEC encoder 630 (i.e., additional information is scrambled by a scrambler 632, which may comprise one or more transforms (e.g., transforms 100, 104), perhaps taking the form of LFSRs. The operation of the scrambler 632 may be influenced by POLY and SEED values selected by the transmission selector 634, which may in turn be selected as fixed or variable values, perhaps according to metric optimization calculations. The selected SEED and POLY values may be provided to the concatenated sequence 620, as well as to the scrambler 632.

The output of the scrambler 632 is modulated by the modulator 636 (e.g., an OFDM or DSSS modulator), before entering the communications channel 614 (e.g., the formation or drill string) as transformed data 638. The transformed data 638 may be amplified using a power amplifier (not shown at the output of the transmitter 610).

A receiver 612 can operate to receive the transformed data 638, which is demodulated by the demodulator 656 to provide demodulated data. A descrambler 652 (which may be similar to or identical to the scrambler 632) can operate on the demodulated data to provide descrambled data. A FEC decoder 650 can apply the error correcting code(s) to the descrambled data to provide a decoded data sequence 640, which may include the configuration description.

The demodulator 656 may provide either hard or soft detection. If soft detection is used, the payload bits may be estimated by the estimator 642 and selectively applied, using the selector 644, so that the correct CRC appears, as calculated by the received CRC processor 646.

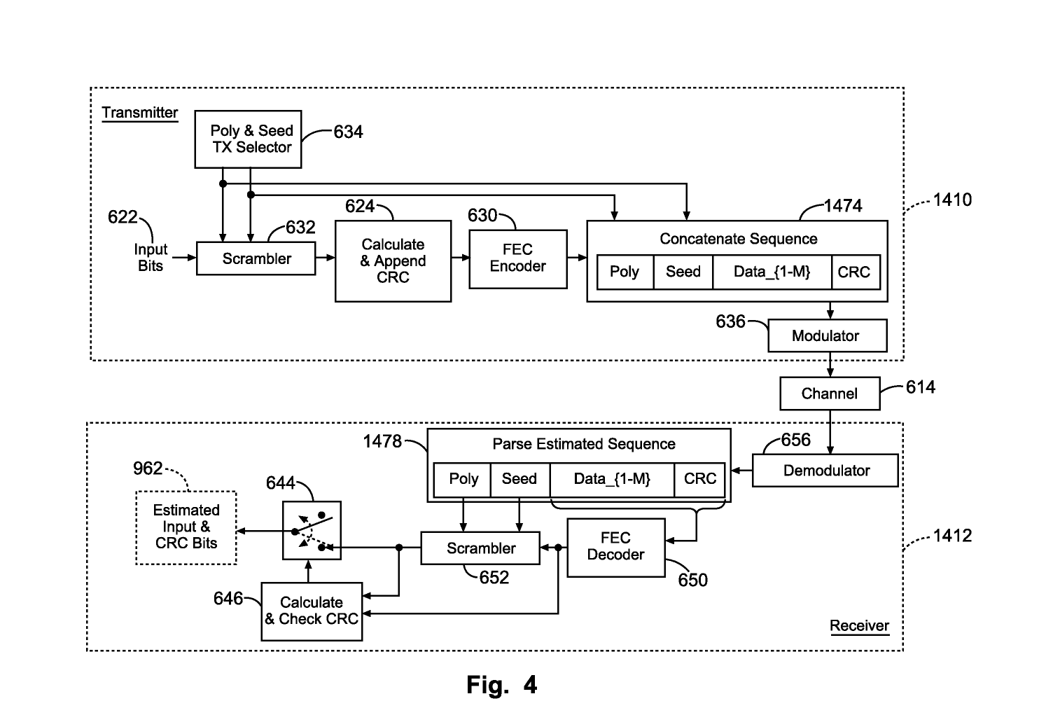

FIG. 4 illustrates a block diagram of a transmitter 1410 and receiver 1412, according to various embodiments of the invention. In this case, the order of the components of the transmitter 610 and receiver 612 shown in FIG. 3 have been re-arranged. The location and composition of the concatenated sequence 1474 has also been changed, resulting in a change of the composition of the decoded data sequence 1478. This permits processing the acquired data (e.g., input bits 622) differently than what is available with respect to the arrangements shown in FIG. 3, providing essentially different transmitter/receiver combinations 1410, 1412, and different estimated input and CRC bits 962. Indeed, many other configurations of the components shown in FIGS. 3-4 may be used to realize various embodiments.

### Apparatus

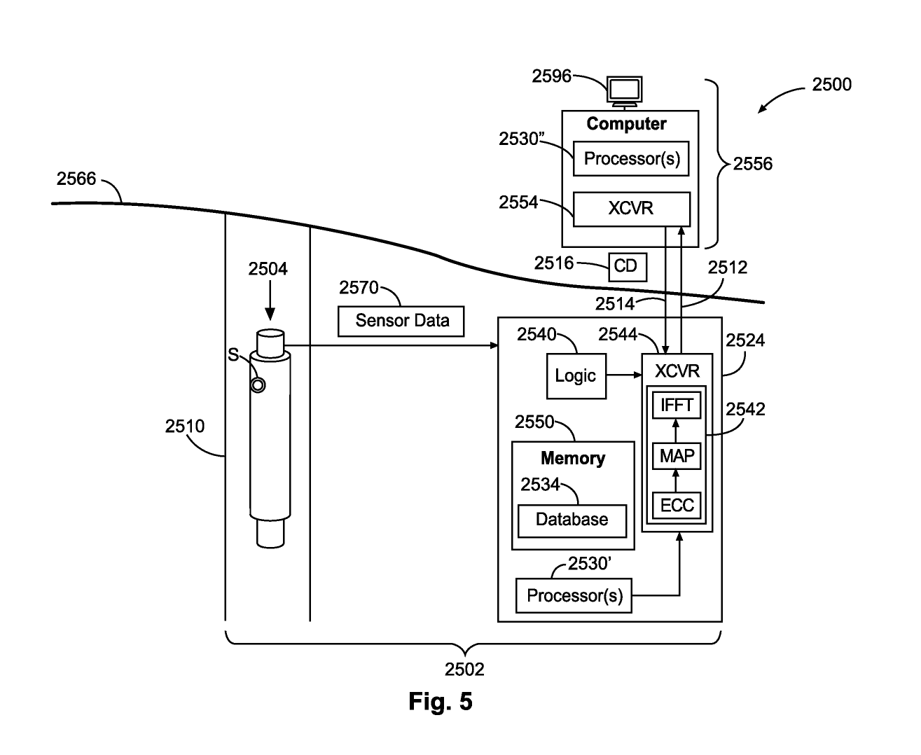

FIG. 5 is a block diagram of apparatus 2502 and systems 2500 according to various embodiments of the invention. In some embodiments, a system 2500 includes a housing 2504. The housing 2504 might take the form of a wireline tool body, or a down hole tool. Processor(s) 2530 within the system 2500 may be located at the surface 2566 (e.g., surface processors 2530″), as part of a surface logging facility 2556, or in a data acquisition system 2524, which may be above or below the Earth's surface 2566 (e.g., attached to the housing 2504 as down hole processors 2530′).

The system 2500 may further comprise a data transceiver 2544 (e.g., a multi-stream transmitter 2542, such as an OFDM transmitter, and a receiver) to transmit sensor data 2570 (e.g., measured compressional wave velocity data, and other data) acquired from sensors S to the surface logging facility 2556. Another transceiver 2544 may be located at the surface 2566, perhaps forming part of the logging facility 2556. The transceivers 2544 may each contain one or more transmitters and receivers, similar to or identical to the transmitters and receivers illustrated in FIGS. 3-4.

Thus, the apparatus 2502 may comprise any one or more of the transmitters and/or receivers shown in FIGS. 3-4. Moreover, any one or more of the transmitters and/or receivers shown in FIGS. 3-4 may include scramblers that operate according to one or more of the transforms shown in FIG. 1. Bit stream formats similar to or identical to that shown in FIG. 2 may be used, if desired.

Logic 2540 (e.g., data acquisition logic) can be used to acquire the data 2570 as signals, which may be encoded according to the various modulation methods described herein. Acquired data 2570, as well as other data, can be stored in the memory 2550, perhaps as part of a database 2534. The database 2534 can also be used to store configuration descriptions and/or tables describing SNR gain as a function of data rate, in some embodiments.

In some embodiments, the functions of the processors 2530 can be accomplished using a single processor, or a group of processors, operating at a single location—either at the surface 2566 or down hole. The functions of the processor(s) 2530 can also be divided, as shown in FIG. 5.

For example, in some embodiments, a first set of processors 2530′ located down hole perform functions such as: encoding bits using a selected error correction code (e.g., using the error correction code module ECC), mapping bits to constellation points using the mapping module MAP, and converting complex constellation points to a real time signal (e.g., using a transformation module IFFT, which may comprise an inverse fast fourier transform module). The real time signal may be transmitted via the primary (uplink) channel 2512, such as the formation below the surface 2566, to the second set of processors 2530″.

In these embodiments, a second set of processors 2530″ located on the surface 2566 perform functions such as: calculating the signal attenuation and SNR for the primary channel 2512, calculating the best bit loading, calculating the best error correction rate, calculating the best number of carriers, and transmitting the best configuration, as set forth in the configuration description, back to the first set of processors 2530′ using a secondary (downlink) channel 2514, such as a mud pulse channel.

A variety of information may be stored in memories, such as memory (not explicitly shown) included in the workstation 2556, or in the memory 2550. Such information may include a table of empirically determined SNR gains (see Table I herein), SNR margin, and total available power, etc.

The transmitter 2542 may comprise an OFDM transmitter, with an error correction code module ECC, a mapping module MAP, and a transformation module IFFT. The error correction code module ECC may operate as an encoder to add parity bits to information bits acquired from a data source (e.g., any combination of sensors S) according to a selected ECC scheme.

The output of the error correction code module ECC is coupled to the mapping module MAP. The role of the mapping module MAP is to take the number of bits allocated for each sub-carrier and convert them into a complex number in the frequency domain based on the constellation selected for that sub-carrier. The mapping module MAP can also operate to increase or decrease the power of each sub-carrier by increasing or decreasing it's amplitude by a constant gain. The output of the mapping module MAP is coupled to the transformation module IFFT, which takes all these complex numbers and converts them to a time domain signal.

In the most general case, the number of bits B needed to describe a configuration in the configuration description can be calculated as shown in equation (1):

B=N*(log 2(M+1)+log 2(L))+log 2(NC), (1)

where a total of N sub-carriers are used, with M being the number of available options for the number of bits/sub-carrier. The number of power levels allowed for each sub-carrier is L. NC is the number of ECC rates possible, with an ECC rate ik=K/N, where K is the average number of information bits, and N is the total number of information bits plus the total number of parity bits.

The highest possible ECC rate is 1.0 (e.g., where no error correction is used). When ECC is used, the ECC rate R is less than 1.0. In one embodiment N=32, M=6, L=8, and NC=5. This gives a configuration description with B=195 bits. The mechanism described herein operates to reduce this value.

One way to reduce the value of B is to implement simplifying assumptions. The first simplification is to keep the transmit power substantially flat. If the number of bits/sub-carrier is changed so as to keep the SNR close to constant, the loss in transmission capacity will be relatively small. As a result, some embodiments have only one power level for each sub-carrier, which means that log 2(L) is multiplied by 1 instead of by N in equation (1).

A second simplification arises from recognizing that the bit rate improvement to be gained by loading different carriers with different number of bits when ECC is used is also very small. The use of error correction takes care of correcting the errors caused by the channels with a low SNR. This means that using the same number of bits per sub-carrier for all carriers (i.e., log 2(M+1) is multiplied by 1 instead of by N in equation (1)) will again result in a small bit rate loss.

A third simplification results from viewing the formation as a communication channel coupled to a low pass filter. This means that the search for sub-carriers can be limited to the highest carrier frequency that can be used at a given depth, because sub-carriers having a higher frequency also have a higher attenuation. This also assumes there are no “holes” in the carrier list, which may or may not be valid if strong interfering tones are present. However, it can also be assumed that an errors induced by such activity will be corrected by the ECC mechanism.

### Methods

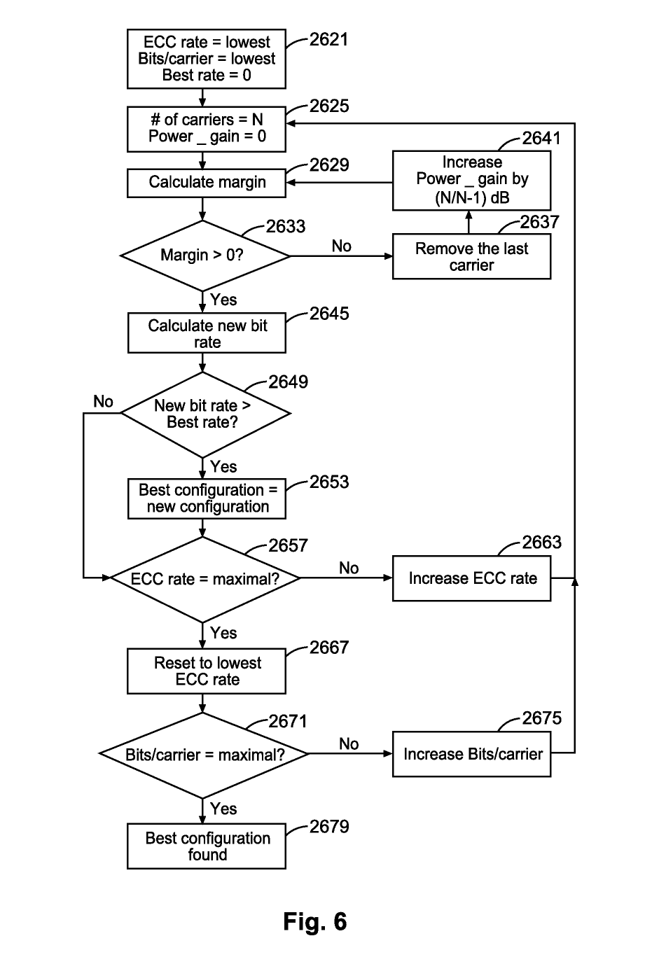

FIG. 6 is a flow chart illustrating several methods 2611 according to various embodiments of the invention. The methods 2611 may comprise processor-implemented methods, to execute on one or more processors (e.g., the processors 2530 in FIG. 5) that perform the methods. These methods 2611 can be used as a searching mechanism to determine the content of the configuration description based on the measured SNR, and may be applied to a number of configurations of the apparatus 2502 and systems 2500 shown in FIG. 5.

In some embodiments, a method 2611 may begin at block 2621 with setting some initial values related to individual sub-carriers. First, it is assumed that a total of N sub-carriers are available. Second, the ECC rate is set to the lowest possible. That is, the constellation is set to the lowest available error correction rate. For example, in a set of available ECC rates having members {½, ⅔, ¾, ⅚} where members are denoted as a/b=a information bits over b information plus parity bits, the rate ik=½ is selected. Third, the number of bits/sub-carrier is set to the lowest available. For example, if the available bits/sub-carrier are part of a set comprising the members {1,2,4,6}, the member having the lowest number of bits/sub-carrier BPC=1 (one bit per sub-carrier) is selected.

At block 2625, the power/sub-carrier is set to P/N, where P is the total power available over all sub-carriers. The best total information bit rate is set to O.

At block 2629 T, which is the total SNR margin, is calculated as a function of the current constellation and the ECC rate. This is shown in equation (2), as follows:

$$T ( id , ik ) - {\sum }_{irecurriers} ( 20 * log 10 ( d min ( id ) / MSE ( ir ) ) - {snr\_gain}_{( id , ik )} + Power\_gain - SNR\_THRESHOLD ) \qquad ( 2 )$$

where id is the current constellation, and ik is the current ECC rate.

Thus, T is the total signal-to-noise ratio margin for the constellation id (i.e., BPC), and the ECC rate ik. ir is an index that runs over all the carriers used (e.g., ir ε{1:15}), MSE is the mean squared error, or the average error for that carrier over all the bits, where the error is the distance in the complex plane between the received point and the constellation point. dmin=½ the minimum distance between points in the complex plane for the current constellation.

The snr_gain is a value that depends on the ECC rate ik and the constellation. The snr_gain can be found empirically by running simulations (e.g., Monte Carlo) of signal propagation in the desired communication channel, such as a geological formation.

For example, the values used for a specific embodiment of an attenuation algorithm used to determine frequency response in a formation are shown in Table I. Going across the top of the table, from left to right, is the ECC rate ik. Going from the top to the bottom on the left side of the table are the bits/sub-carrier BPC, which determines the constellation size.

TABLE I
SNR gain (in dB) as a function of data rate in a formation

ECC Rate

| Bits per Sub-Carrier | 1/2 | 2/3 | 3/4 | 5/6 |
|---|---|---|---|---|
| 1 | 9.0 | 8.8 | 8.1 | 6.0 |
| 2 | 7.4 | 7.1 | 6.7 | 5.0 |
| 4 | 8.5 | 6.7 | 5.4 | 3.8 |
| 6 | 9.8 | 7.9 | 6.5 | 4.6 |

Power_gain is the extra power added to each carrier after one or more sub-carriers are removed (at block 2637). The value of Power-gain is initialized to zero and increased every time a sub-carrier is removed at block 2637.

The SNR_THRESHOLD is a constant that depends on the Frame Error Rate (FER) allowed in the communications system. It depends on the constellation size, the number of sub-carriers used, and a constant value called the “implementation loss” by those of ordinary skill in the art. In one embodiment, an SNR_THRESHOLD value of 20 dB is used. As is known by those of ordinary skill in the art, a quality function Q, with an assumed Gaussian noise distribution, can be used to calculate the SNR_THRESHOLD value for a desired FER

The total margin T should be greater than zero. If it's not, as determined at block 2633, the last sub-carrier is removed at block 2637 to adjust the number of carriers used to transmit information. This means that the power per sub-carrier can be increased by a factor of N/N−1 to keep the total power constant. Increasing the power means increasing the SNR by the same factor (assuming the noise is independent of the signal). The power gain of 10*log₁₀(N/N−1) is added to the SNR margin of each sub-carrier at block 2641 and the total margin T is re-calculated at block 2629.

Once the total margin T is found to be greater than zero at block 2633, the new bit rate BR is calculated at block 2645, using equation (3) as follows:

BR=BPC*ik*N/t (3)

where BPC is the number of bits/sub-carrier, ik is the ECC rate, N is the number of sub-carriers, and t is the time each symbol (e.g., OFDM symbol) takes to transmit.

The newly-calculated bit rate BR is calculated and compared to the best rate so far, at block 2649. If the newly-calculated rate is higher than the current rate, as determined at block 2649, the current rate is updated to the newly-calculated rate, and the configuration description is revised to reflect the new configuration at block 2653. If newly-calculated bit rate BR is not greater than current best rate, then the current rate is retained, and the configuration description is not revised.

At block 2657, the current ECC rate ik is compared to the maximal ECC rate available. If the current ECC rate ik is not the maximal available rate (e.g., ⅚ in Table I), then the ECC rate ik is increased at block 2663 to the next higher rate in the table, the number of carriers N is reset to the maximum amount available, and the process of evaluating the total margin T, the bit rate, and the ECC rate ik begins again at block 2625.

On the other hand, if the current ECC rate ik is equal to the maximal available rate, then the ECC rate ik is reset back to the lowest available rate (e.g., ½ in Table I) at block 2667, and the number of bits/sub-carrier is compared to the highest possible value at block 2671.

Thus, at block 2671, the number of bits/sub-carrier is compared to the highest available value (e.g., “6” in Table I). If the number of bits/sub-carrier is not set to the highest value, then the number of bits/sub-carrier is increased to the next higher value, and the evaluation process begins again at block 2625.

On the other hand, if the number of bits/sub-carrier is equal to the highest available value, as determined at block 2671, then method 2611 ends, because the best configuration has been found.

The configuration description comprises at least three constants: the best constellation, the best ECC rate, and the number of sub-carriers to be used. In one embodiment 32 sub-carriers are used with NC=5 different ECC rates ik, and M=5 different constellations. Given the simplifications noted previously, the total number of bits needed to transmit the associated configuration description is shown in equation (4) as follows:

B=log 2(NC)+log 2(M)+log 2(N)=11 (4)

Indeed, in some embodiments, it can be shown that some of the combinations are redundant. For example, a constellation of four bits/sub-carrier with an ECC rate of ik=¾ gives an effective communication rate of three data bits per sub-carrier. The same effective communication rate is obtained by using a constellation of 6 bits/carrier and an ECC rate of ½. However, the latter combination has a lower SNR_gain, so it can be removed from the configuration list. By removing all extra redundant combinations (e.g., removing those redundant configurations in Table I that provide the same effective communication rate, leaving one that has the best SNR)—it has been determined that in this case ten bits are enough to describe all useable configurations. For example, in Table I, two configurations are redundant: (a) R=½ and k=4, and (b) R=⅔ and k=3; each has an effective communication rate of two bits per sub-carrier.

The method 2611 is just one process that can be used to find an optimal configuration of constellation and error correction rate, under the constraint of constant power, while minimizing the number of bits needed to describe the configuration. In some cases, the method 2611 has been found to reduce the number of bits used to describe the configuration by a factor of almost twenty times, with only a small loss of communication channel performance.

In some embodiments, a surface computer can determine channel attenuation based on received data, to calculate a new configuration description that can be fed back down hole via mud pulse transmission. Many other divisions of the process can be made. Thus, it can be seen that many embodiments may be realized, and several that include at least some of these features will now be described in detail.

Referring now to FIGS. 5 and 6, it can be seen that in a basic system, two processors 2530′ and 2530″ communicate with each other, and a transmitter (e.g., forming part of a transceiver 2544) may be used to send information from one processor 2530′ to another processor 2530″ using an uplink channel 2512. In most embodiments, the methods of FIG. 6 can be used to find a new configuration for transmission from the surface processor 2530″ to the down hole processor 2530′, using a downlink channel 2514, after the uplink signal has been received and evaluated by the surface processor 2530″.

The uplink channel 2512 conveys data and other information determined by down hole instrumentation to the surface processor 2530″, and may comprise drilling mud, the formation, a wire line, a drill string, and/or repeaters. The downlink (feedback) channel 2514 conveys a configuration description 2516 to the down hole processor 2530′ that is used to format the uplinked information. The configuration description 2516 is revised periodically according to the attenuation and signal-to-noise ratio that exist in the uplink channel 2512, as determined by the surface processor 2530″, taking into account the uplink signal characteristics, and noise at the surface. The downlink channel 2514 can utilize any of the communications mechanisms that are used by the uplink channel 2512. For example, the downlink (feedback) channel 2514 may comprise drilling mud, the formation, a wire line, a drill string, and/or repeaters, perhaps forming a mud pulse telemetry channel.

In some embodiments, the formation can be used as either the uplink channel 2512 or the downlink channel 2514, or both, in one of two modes—half duplex (e.g., TDM—time division multiplexing) or full duplex (e.g., FDM—frequency division multiplexing). In TDM, there are time slots allocated for each communication direction, such as one second for uplink, alternating with a half-second for downlink. In FDM, both uplink and downlink can transmit on different frequencies at the same time. Other options exist for modes of communication, such as CDMA (code division multiple access). Thus many embodiments may be realized.

For example, turning now to FIG. 5, it can be seen that a system 2500 may comprise a first processor 2530′ and a second processor 2530″. The system 2500 may also include a transmitter (e.g., as part of the transceiver 2544) to communicate the uplink channel signal from the first processor 2530′ to the second processor 2530″.

The first processor 2530′ can be configured to to encode sensor data 2570 acquired down hole into an uplink channel signal (carried on the uplink channel 2512, where the encoding is conducted according to a configuration description that carries the configuration description 2516.

The second processor 2530″ may be configured to calculate channel attenuation associated with the uplink channel signal, and to determine a uniform number of bits per sub-carrier and an error correction rate forming part of a system configuration to maximize an effective bit transmission rate while minimizing a size of the configuration description. This can be accomplished by using a predetermined number of bits in the configuration description, with the predetermined number determined according to various methods described herein. The configuration description includes content designating at least the number of bits per sub-carrier, the error correction rate, and the number of sub-carriers.

In some embodiments, an error correction code encoder can be used, with its operation dictated by the error correction rate. Thus, the system 2500 may comprise an error correction code encoder ECC to receive data bits and to add parity bits to the data bits, based on the error correction rate.

In some embodiments, a mapper can be used to distribute available power to a number of sub-carriers determined by the total signal-to-noise ratio margin. Thus, the system 2500 may comprise a mapper MAP to adjust power to be uniformly applied to each of the number of sub-carriers, based on a total signal-to-noise ratio margin that is used to determine the number of sub-carriers.

In some embodiments, a transformation module, such as an IFFT module, can be used to receive input from the mapper, and to construct the signal that, upon reception, can be used to determine channel attenuation. Thus, the system 2500 may comprise a transformation module IFFT (which may operate to implement an inverse fast Fourier transform process, among others) to receive complex numbers from the mapper MAP, and to transform the complex numbers into a signal, comprising a portion of a time-domain signal that is to be sent on the uplink channel 2512.

In some embodiments, a memory can be used to store a table of signal-to-noise ratio gain, such as Table I, which is directly or indirectly used to determine the number of sub-carriers. Thus, the system 2500 may comprise a memory 2550 to store a lookup table (e.g., in the database 2534) of empirically determined signal-to-noise ratio gain, the signal-to-noise ratio gain being used to determine a total signal-to-noise ratio margin that is in turn used to determine the number of sub-carriers.

In some embodiments, the system may include a down hole tool. Thus, the system 2500 may comprise a down hole tool (e.g., forming the housing 2504) to house the first processor and the transmitter.

In some embodiments, an acoustic sensor (e.g., transducer) may be used to receive acoustic signals, after they have interacted with the formation surrounding the housing 2504. Thus, the system 2500 may comprise one or more sensors S, such as an acoustic sensor, attached to the housing 2504. The sensors S can be used to receive acoustic signals associated with measured compressional wave velocity data. The housing 2504 may comprise a wireline tool or a down hole tool, such as a logging while drilling tool or a measurement while drilling tool, among others.

In the system 2500, the processors 2530 may be housed by the housing 2504, or by a surface data processing facility 2556, or both, depending on where various calculations are to be made. Thus, processing during various activities conducted by the system 2500 may be conducted both down hole and at the surface 2566. Each of the processors 2530 may comprise multiple computational units, some located down hole, and some at the surface 2566.

In some embodiments, the system 2500 comprises a second transmitter (e.g., a transmitter in the surface transceiver 2544) coupled to a second processor (e.g., the processors 2530″) to transmit a new configuration description 2516 within a downlink signal over the downlink channel 2514 to a second receiver (e.g., a receiver in the down hole transceiver 2544) coupled to a first processor (e.g., processors 2530′). The first processor can be configured to modify a subsequent transmission of an uplink channel signal or a time-domain signal transmission configuration on the uplink channel 2512 after receiving the new configuration description 2516.

In some embodiments, the new configuration description comprises a limited number of bits enabling identification of a number of sub-carriers used in the subsequent transmission of said uplink channel signal or the time-domain signal transmission configuration. In some embodiments, the new configuration description comprises a limited number of bits identifying an FEC code rate used in the subsequent transmission of the uplink channel signal or the time-domain signal transmission configuration. In some embodiments, the new configuration description comprises a limited number of bits identifying of a modulation order used uniformly across sub-carriers in the subsequent transmission of said uplink channel signal or said time-domain signal transmission configuration.

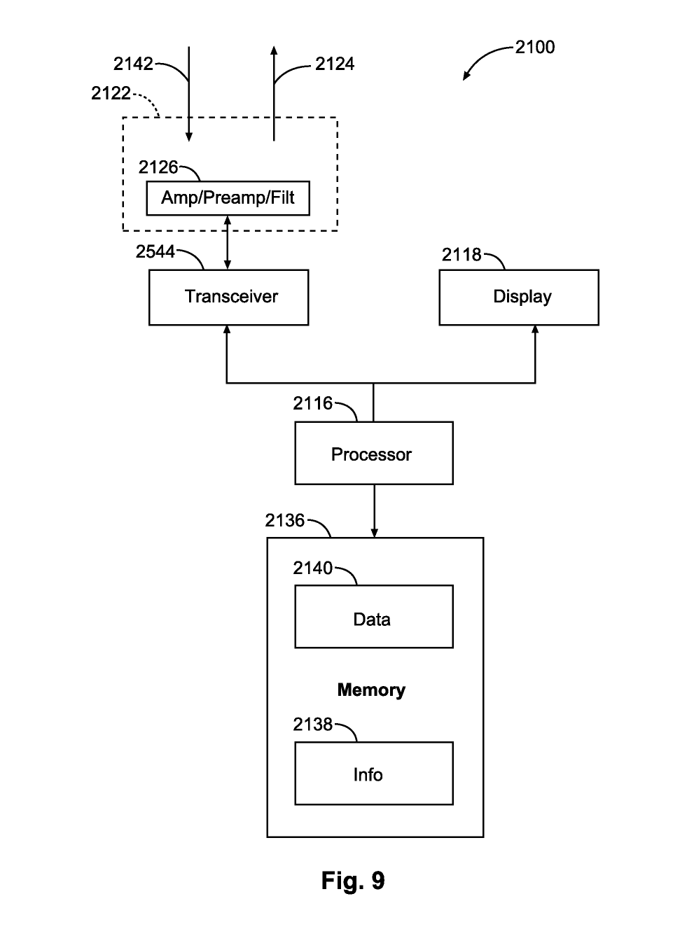

In some embodiments, components in the article 2100 of FIG. 9 may be used as part of the apparatus 2502 and systems 2500. Similarly, the transmitters and receivers of FIGS. 3-4 may be used in place of various components in the transceiver 2544 of FIG. 5.

Turning now to FIG. 6, it can be seen that a number of additional methods may also be realized. For example, a method 2611 may comprise choosing a number of bits per sub-carrier (uniformly applied, so each sub-carrier has the same number of bits) and an error correction rate from sets of limited size to maximize an effective bit transmission rate, while minimizing the size of the configuration description. This may be accomplished as part of a number of activities.

In some embodiments, a method 2611 includes determining a uniform number of bits per sub-carrier (e.g., at block 2671) and an error correction rate (e.g., at block 2657) as part of a communication system configuration to maximize an effective bit transmission rate (e.g., at block 2649) while minimizing a size of a configuration description. The configuration description being used to designate at least the number of bits per sub-carrier, the error correction rate, and a number of sub-carriers.

In some embodiments, the total SNR margin can be used to determine the number of sub-carriers. Thus, determining the uniform number of bits may comprise calculating a total SNR margin (e.g., at block 2629) to determine the number of sub-carriers.

If the total SNR margin is not a positive value (e.g., as determined at block 2633), then the number of sub-carriers is reduced. Thus, the method 2611 may comprise reducing the number of sub-carriers to provide a reduced number of sub-carriers when the total signal-to-noise ratio margin is not greater than zero.

If the number of sub-carriers is reduced, based on a non-positive total SNR margin, the power gain for the remaining sub-carriers can be increased. Thus, the method 2611 may comprise uniformly increasing the power gain (e.g., at block 2641) for each one of the reduced number of sub-carriers.

The total SNR margin can be empirically determined Thus, calculating the total SNR margin as part of the method 2611 may comprise calculating the total SNR margin as a function of an empirically determined SNR gain.

The process of empirical determination may include simulation, such as a Monte-Carlo simulation. Thus, empirical determination, as part of the method 2611, may comprise simulating geological formation attenuation to determine a frequency response of the geological formation.

In many embodiments, when the total SNR margin is positive, a new effective bit transmission rate is calculated. Thus, determining the uniform number of bits per sub-carrier and an error correction rate may comprise calculating a new version of the effective bit transmission rate based on a total SNR margin that is greater than zero, to determine whether to revise the configuration description.

In some embodiments, when the new effective bit transmission rate is greater than the old one, then the configuration description is revised to reflect the new configuration. Thus, the method 2611 may comprise revising the configuration description when the new version of the effective bit transmission rate is greater than a prior version of the effective bit transmission rate (e.g., at block 2649).

In some embodiments, the error correction rate is increased when a higher rate is available, and the configuration description has been revised due to the discovery of a greater effective bit transmission rate. Thus, the method 2611 may comprise increasing the error correction rate (at block 2663) when a current version of the error correction rate is not the highest available error correction rate, and the configuration description has been revised to include the new version of the effective bit transmission rate.

In some embodiments, the error correction rate is reduced when no higher rate is available, and the configuration description has been revised due to the discovery of a greater effective bit transmission rate. Thus, the method 2611 may comprise reducing the error correction rate (e.g., at block 2667) to the lowest available error correction rate when a current version of the error correction rate is a highest available error correction rate, and the configuration description has been revised to include the new version of the effective bit transmission rate.

In some embodiments, the number of bits per sub-carrier is increased when the error correction rate is reduced, and a higher number of bits per sub-carrier is available for selection. Thus, the method 2611 may comprise increasing the number of bits per sub-carrier (e.g., at block 2675) when the number of bits per sub-carrier is not the highest available bits per sub-carrier.

When the best configuration has been found (e.g., at block 2679), it is often transmitted to a remote location, such as from the surface to a location down hole. Thus, the method 2611 may comprise transmitting the configuration description as a version of the configuration description having a minimal size when the number of bits per sub-carrier is a highest available bits per sub-carrier, the error correction rate is a lowest available error correction rate, and the configuration description has been revised to include a new version of the effective bit transmission rate based on a total SNR margin that is greater than zero.

In some embodiments, the method 2611 may comprise receiving the configuration description remotely, configuring a return transmission signal formatted according to the configuration description, and transmitting the return transmission signal comprising at least in part data sensor information after receiving said configuration description. In some embodiments, the method 2611 may comprise receiving the return transmission signal formatted according to the configuration description, and estimating the data sensor information acquired remotely and transmitted in a format described by the configuration description. Therefore, in some embodiments, the method 2611 comprises transmitting a new configuration description within a downlink signal to a down hole receiver to enable modification of a subsequent transmission on an uplink channel signal or a time-domain signal transmission configuration based on the new configuration description.

An indexed look-up table (e.g., similar to or identical to Table I) of empirically determined SNR gain can be used to help calculate the total SNR margin, that is in turn used to determine the number of sub-carriers. Thus, the method 2611 may comprise accessing a lookup table of empirically determined SNR gain, indexed by the number of bits per sub-carrier and the error correction rate, to enable calculation of a total SNR margin (e.g., at block 2629) that is used to determine the number of sub-carriers.

It should be noted that the methods described herein do not have to be executed in the order described, or in any particular order. Moreover, various activities described with respect to the methods identified herein can be executed in iterative, serial, or parallel fashion. The various elements of each method can be substituted, one for another, within and between methods.

Information, including parameters, commands, operands, and other data, can be sent and received in the form of one or more carrier waves. Still further embodiments may be realized.

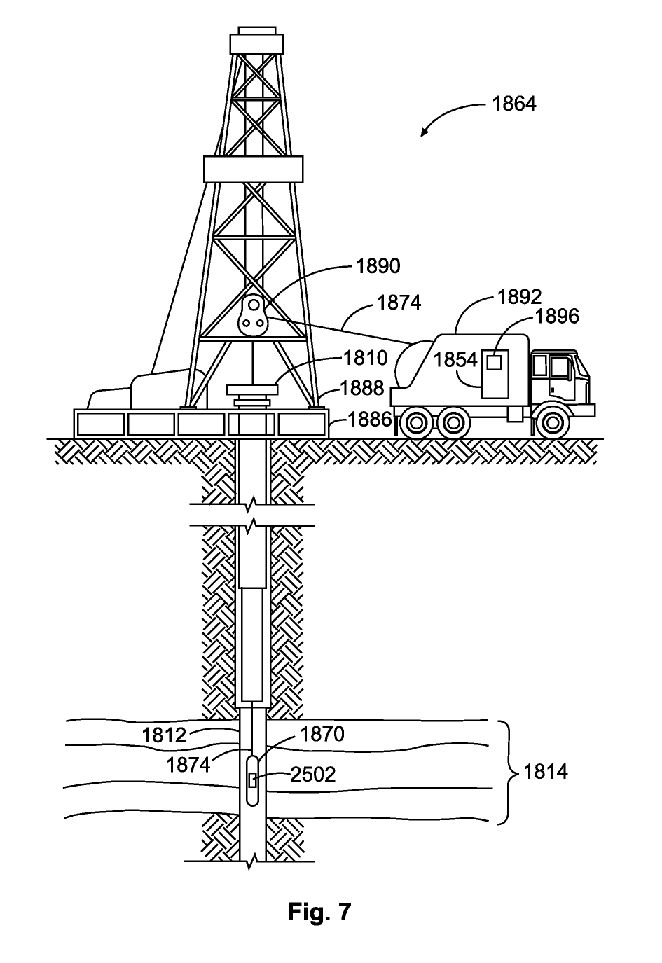

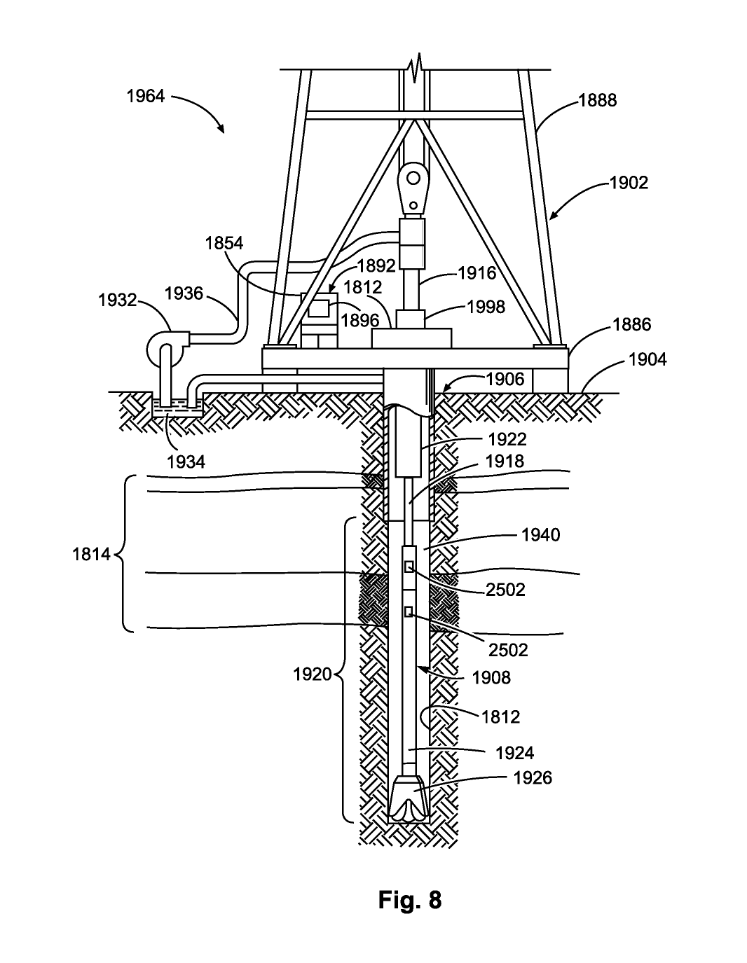

For example, FIG. 7 illustrates a wireline system 1864 embodiment of the invention. FIG. 8 illustrates a drilling rig system 1964 embodiment of the invention. Thus, the systems 1864, 1964 may comprise portions of a tool body 1870 as part of a wireline logging operation, or of a downhole tool 1924 as part of a downhole drilling operation.

FIG. 7 shows a well during wireline logging operations. Here, a drilling platform 1886 is equipped with a derrick 1888 that supports a hoist 1890.

Drilling of oil and gas wells is commonly carried out using a string of drill pipes connected together so as to form a drilling string that is lowered through a rotary table 1810 into a wellbore or borehole 1812. Here it is assumed that the drilling string has been temporarily removed from the borehole 1812 to allow a wireline logging tool body 1870, such as a probe or sonde, to be lowered by wireline or logging cable 1874 into the borehole 1812. Typically, the tool body 1870 is lowered to the bottom of the region of interest and subsequently pulled upward at a substantially constant speed.

During the upward trip, at a series of depths the instruments (e.g., the apparatus 2502 shown in FIG. 5) included in the tool body 1870 may be used to perform measurements on the subsurface geological formations 1814 adjacent the borehole 1812 (and the tool body 1870). The measurement data can be communicated to a surface logging facility 1892 for storage, processing, and analysis. Communication of the data may occur using any of the systems and apparatus described herein. The logging facility 1892 may be provided with electronic equipment for various types of signal processing, which may be implemented by any one or more of the components of the system 2500 or apparatus 2502 in FIG. 5. Similar formation evaluation data may be gathered and analyzed during drilling operations (e.g., during LWD operations, and by extension, sampling while drilling).

In some embodiments, the tool body 1870 comprises a formation resistivity tool for obtaining and analyzing resistivity measurements from a subterranean formation through a wellbore. The formation resistivity tool is suspended in the wellbore by a wireline cable 1874 that connects the tool to a surface control unit (e.g., comprising a workstation 1854). The formation resistivity tool may be deployed in the wellbore on coiled tubing, jointed drill pipe, hard wired drill pipe, or any other suitable deployment technique.

Turning now to FIG. 8, it can be seen how a system 1964 may also form a portion of a drilling rig 1902 located at the surface 1904 of a well 1906. The drilling rig 1902 may provide support for a drill string 1908. The drill string 1908 may operate to penetrate a rotary table 1810 for drilling a borehole 1812 through subsurface formations 1814. The drill string 1908 may include a Kelly 1916, drill pipe 1918, and a bottom hole assembly 1920, perhaps located at the lower portion of the drill pipe 1918.

The bottom hole assembly 1920 may include drill collars 1922, a downhole tool 1924, and a drill bit 1926. The drill bit 1926 may operate to create a borehole 1812 by penetrating the surface 1904 and subsurface formations 1814. The downhole tool 1924 may comprise any of a number of different types of tools including MWD (measurement while drilling) tools, LWD tools, and others.

During drilling operations, the drill string 1908 (perhaps including the Kelly 1916, the drill pipe 1918, and the bottom hole assembly 1920) may be rotated by the rotary table 1810. In addition to, or alternatively, the bottom hole assembly 1920 may also be rotated by a motor (e.g., a mud motor) that is located downhole. The drill collars 1922 may be used to add weight to the drill bit 1926. The drill collars 1922 may also operate to stiffen the bottom hole assembly 1920, allowing the bottom hole assembly 1920 to transfer the added weight to the drill bit 1926, and in turn, to assist the drill bit 1926 in penetrating the surface 1904 and subsurface formations 1814.

During drilling operations, a mud pump 1932 may pump drilling fluid (sometimes known by those of skill in the art as “drilling mud”) from a mud pit 1934 through a hose 1936 into the drill pipe 1918 and down to the drill bit 1926. The drilling fluid can flow out from the drill bit 1926 and be returned to the surface 1904 through an annular area 1940 between the drill pipe 1918 and the sides of the borehole 1812. The drilling fluid may then be returned to the mud pit 1934, where such fluid is filtered. In some embodiments, the drilling fluid can be used to cool the drill bit 1926, as well as to provide lubrication for the drill bit 1926 during drilling operations. Additionally, the drilling fluid may be used to remove subsurface formation 1814 cuttings created by operating the drill bit 1926.

Thus, referring now to FIGS. 1-8, it may be seen that in some embodiments, the systems 1864, 1964, 2500 may include a drill collar 1922, a downhole tool 1924, and/or a wireline logging tool body 1870 to house one or more apparatus 2502, similar to or identical to the apparatus 2502 described above and illustrated in FIG. 5. Additional apparatus 2502 may be included in a surface processing facility, such as the workstation 1854. Thus, for the purposes of this document, the term “housing” may include any one or more of a drill collar 1922, a downhole tool apparatus 1924, and a wireline logging tool body 1870 (all having an outer wall, to enclose or attach to instrumentation, sensors, fluid sampling devices, pressure measurement devices, transmitters, receivers, and data acquisition systems). The apparatus 2502 may comprise a downhole tool, such as an LWD tool or MWD tool. The tool body 1870 may comprise a wireline logging tool, including a probe or sonde, for example, coupled to a logging cable 1874. Many embodiments may thus be realized.

For example, in some embodiments, a system 1864, 1964, 2500 may include a display 1896 to present information acquired down hole, both measured and predicted, as well as database information, perhaps in graphic form. A system 1864, 1964, 2500 may also include computation logic, perhaps as part of a surface logging facility 1892, or a computer workstation 1854, to receive signals from transmitters and receivers, and other instrumentation.

Thus, a system 1864, 1964, 2500 may comprise a downhole tool 1924, and one or more apparatus 2502 attached to the downhole tool 1924, the apparatus 2502 to be constructed and operated as described previously. Additional apparatus 2502 may be included at the surface, perhaps in the workstation 1854. In some embodiments, the downhole tool 1924 comprises one of a wireline tool or an MWD tool.

The apparatus 2502, and any components included therein may all be characterized as “modules” herein. Such modules may include hardware circuitry, and/or a processor and/or memory circuits, software program modules and objects, and/or firmware, and combinations thereof, as desired by the architect of the apparatus 2502 and systems 1864, 1964, 2500 and as appropriate for particular implementations of various embodiments. For example, in some embodiments, such modules may be included in an apparatus and/or system operation simulation package, such as a software electrical signal simulation package, a power usage and distribution simulation package, a power/heat dissipation simulation package, and/or a combination of software and hardware used to simulate the operation of various potential embodiments.

It should also be understood that the apparatus and systems of various embodiments can be used in applications other than for logging operations, and thus, various embodiments are not to be so limited. The illustrations of apparatus 2502 and systems 1864, 1964, 2500 are intended to provide a general understanding of the structure of various embodiments, and they are not intended to serve as a complete description of all the elements and features of apparatus and systems that might make use of the structures described herein.

Applications that may include the novel apparatus and systems of various embodiments include electronic circuitry used in high-speed computers, communication and signal processing circuitry, modems, processor modules, embedded processors, data switches, and application-specific modules. Such apparatus and systems may further be included as sub-components within a variety of electronic systems, such as televisions, cellular telephones, personal computers, workstations, radios, video players, vehicles, signal processing for geothermal tools and smart transducer interface node telemetry systems, among others. Some embodiments include a number of methods.

### Articles of Manufacture

Upon reading and comprehending the content of this disclosure, one of ordinary skill in the art will understand the manner in which a software program can be launched from a computer-readable medium in a computer-based system to execute the functions defined in the software program. One of ordinary skill in the art will further understand the various programming languages that may be employed to create one or more software programs designed to implement and perform the methods disclosed herein. The programs may be structured in an object-orientated format using an object-oriented language such as Java or C#. In some embodiments, the programs can be structured in a procedure-orientated format using a procedural language, such as assembly or C. The software components may communicate using any of a number of mechanisms well known to those skilled in the art, such as application program interfaces or interprocess communication techniques, including remote procedure calls. The teachings of various embodiments are not limited to any particular programming language or environment. Thus, other embodiments may be realized.

For example, FIG. 9 is a block diagram of an article 2100 according to various embodiments of the invention, such as a computer, a memory system, a magnetic or optical disk, or some other storage device. The article 2100 may include one or more processors 2116 coupled to a machine-accessible medium such as a memory 2136 (e.g., removable storage media, as well as any tangible, non-transitory memory including an electrical, optical, or electromagnetic conductor) having associated information 2138 (e.g., computer program instructions and/or data), which when executed by one or more of the processors 2116, results in a machine (e.g., the article 2100) performing any actions described with respect to the apparatus, systems, and methods of FIGS. 1-8.

In some embodiments, the article 2100 may comprise one or more processors 2116 coupled to a display 2118 to display data processed by the processor 2116 and/or a wired or wireless transceiver 2544 (e.g., a downhole telemetry transceiver) to receive and transmit data processed by the processor.

The memory system(s) included in the article 2100 may include memory 2136 comprising volatile memory (e.g., dynamic random access memory) and/or non-volatile memory. The memory 2136 may be used to store data 2140 processed by the processor 2116, such as data acquired by down-hole tool instrumentation.

In various embodiments, the article 2100 may comprise communication apparatus 2122, which may in turn include amplifiers 2126 (e.g., preamplifiers or power amplifiers) and/or filters (e.g., interpolation filters, noise reduction filters, etc.). Signals 2142 received or transmitted by the communication apparatus 2122 may be processed according to the methods described herein.

Many variations of the article 2100 are possible. For example, in various embodiments, the article 2100 may comprise a downhole tool, such as the tool apparatus 2502 shown in FIG. 5.

In summary, the apparatus, systems, and methods disclosed herein may operate to allocate the best configuration description for a communication system (e.g., such as a down hole to surface data communication system), so that the total bit rate achieved can be maximized while keeping the bit error rate below a desired level. This is accomplished using a configuration description of reduced size. As a result, the time spent communicating information from the surface down hole, and vice versa, may be substantially reduced, enhancing the value of services provided by an operation/exploration company.

The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

The Abstract of the Disclosure is provided to comply with 37 C.F.R. §1.72(b), requiring an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment.

What is claimed is:

1. A system, comprising:
a first processor to encode sensor data acquired down hole into an uplink channel signal, the encoding conducted according to a configuration description;
a second processor to calculate channel attenuation associated with the uplink channel signal, and to determine a uniform number of bits per sub-carrier and an error correction rate forming part of a system configuration to maximize an effective bit transmission rate while using a predetermined number of bits in the configuration description, the configuration description having content designating at least the number of bits per sub-carrier, the error correction rate, and a number of sub-carriers; and
a transmitter to communicate the uplink channel signal from the first processor to the second processor.

2. The system of claim 1, further comprising:
an error correction code encoder to receive data bits and to add parity bits to the data bits, based on the error correction rate.

3. The system of claim 1, further comprising:
a mapper to adjust power to be uniformly applied to each of the number of sub-carriers, based on a total signal-to-noise ratio margin that is used to determine the number of sub-carriers.

4. The system of claim 1, further comprising:
a transformation module to receive complex numbers from the mapper, and to transform the complex numbers into the uplink channel signal, comprising a portion of a time-domain signal.

5. The system of claim 1, further comprising:
a memory to store a lookup table of empirically determined signal-to-noise ratio gain, the signal-to-noise ratio gain being used to determine a total signal-to-noise ratio margin that is in turn used to determine the number of sub-carriers.

6. The system of claim 1, further comprising:
a down hole tool to house the first processor and the transmitter.

7. The system of claim 1 further comprising:
a second transmitter coupled to said second processor to transmit a new configuration description within a downlink signal to a second receiver coupled to said first processor, wherein the first processor is configured to modify a subsequent transmission of said uplink channel signal or a time-domain signal transmission configuration after receiving said new configuration description.

8. The system in claim 7, wherein the new configuration description comprises a limited number of bits enabling identification of a number of sub-carriers used in the subsequent transmission of said uplink channel signal or said time-domain signal transmission configuration.

9. The system in claim 7, wherein the new configuration description comprises a limited number of bits identifying a Forward Error Correction code rate used in the subsequent transmission of said uplink channel signal or said time-domain signal transmission configuration.

10. The system in claim 7, wherein the new configuration description comprises a limited number of bits identifying of a modulation order used uniformly across sub-carriers in the subsequent transmission of said uplink channel signal or said time-domain signal transmission configuration.

11. A processor-implemented method to execute on one or more processors that perform the method, comprising:
determining a uniform number of bits per sub-carrier and an error correction rate as part of a communication system configuration to maximize an effective bit transmission rate while using a predetermined number of bits in a configuration description, the configuration description designating at least the number of bits per sub-carrier, the error correction rate, and a number of sub-carriers.

12. The method of claim 11, wherein the determining comprises:
calculating a total signal-to-noise ratio margin to determine the number of sub-carriers.

13. The method of claim 12, further comprising:
reducing the number of sub-carriers to provide a reduced number of sub-carriers when the total signal-to-noise ratio margin is not greater than zero.

14. The method of claim 13, further comprising:
uniformly increasing the power gain for each one of the reduced number of sub-carriers.

15. The method of claim 12, wherein the calculating comprises:
calculating the total signal-to-noise ratio margin as a function of an empirically determined signal-to-noise ratio gain.

16. The method of claim 15, wherein empirical determination comprises:
simulating geological formation attenuation to determine a frequency response of the geological formation.

17. The method of claim 11, wherein the determining comprises:
calculating a new version of the effective bit transmission rate based on a total signal-to-noise ratio margin that is greater than zero, to determine whether to revise the configuration description.

18. The method of claim 17, further comprising:
revising the configuration description when the new version of the effective bit transmission rate is greater than a prior version of the effective bit transmission rate.

19. The method of claim 18, comprising:
increasing the error correction rate when a current version of the error correction rate is not a highest available error correction rate and the configuration description has been revised to include the new version of the effective bit transmission rate.

20. The method of claim 18, further comprising:
reducing the error correction rate to a lowest available error correction rate when a current version of the error correction rate is a highest available error correction rate and the configuration description has been revised to include the new version of the effective bit transmission rate.

21. The method of claim 20, further comprising:
increasing the number of bits per sub-carrier when the number of bits per sub-carrier is not a highest available bits per sub-carrier.

22. The method of claim 11, further comprising:
receiving said configuration description remotely;
configuring a return transmission signal formatted according to said configuration description; and
transmitting said return transmission signal comprising at least in part data sensor information after receiving said configuration description.

23. The method of claim 22, further comprising:
receiving said return transmission signal formatted according to said configuration description; and
estimating said data sensor information acquired remotely and transmitted in a format described by the configuration description.

24. An article including a non-transitory, machine-accessible medium having instructions stored therein, wherein the instructions, when executed, result in a machine performing:
determining a uniform number of bits per sub-carrier and an error correction rate as part of a communication system configuration to maximize an effective bit transmission rate while using a predetermined number of bits in a configuration description, the configuration description designating at least the number of bits per sub-carrier, the error correction rate, and a number of sub-carriers.

25. The article of claim 24, wherein the instructions, when executed, result in the machine performing:
transmitting the configuration description as a version of the configuration description having a minimal size when the number of bits per sub-carrier is a highest available bits per sub-carrier, the error correction rate is a lowest available error correction rate, and the configuration description has been revised to include a new version of the effective bit transmission rate based on a total signal-to-noise ratio margin that is greater than zero.

26. The article of claim 24, wherein the determining further comprises:
accessing a lookup table of empirically determined signal-to-noise ratio gain, indexed by the number of bits per sub-carrier and the error correction rate, to enable calculation of a total signal-to-noise ratio margin that is used to determine the number of sub-carriers.

27. The article of claim 24, wherein the instructions, when executed, result in a machine performing:
transmitting a new configuration description within a downlink signal to a down hole receiver to enable modification of a subsequent transmission on an uplink channel signal or a time-domain signal transmission configuration based on the new configuration description.
